(19) United States
(12) Patent Application Publication
(10) Pub. No.: US 2021/0084751 A1
(43) Pub. Date: Mar. 18, 2021

(54) Printed Wiring Board

(71) Applicant: Tatsuta Electric Wire & Cable Co., Ltd., Osaka (JP)

(72) Inventors: Yuusuke HARUNA, Kyoto (JP); Takahiko KATSUKI, Kyoto (JP); Tsuyoshi HASEGAWA, Kyoto (JP); Hiroshi TAJIMA, Kyoto (JP)

(73) Assignee: Tatsuta Electric Wire & Cable Co., Ltd.

(21) Appl. No.: 17/106,438

(22) Filed: Nov. 30, 2020

Related U.S. Application Data
(63) Continuation of application No. 16/480,247, filed on Jul. 23, 2019.

(30) Foreign Application Priority Data
Feb. 13, 2017 (JP) 2017-024499

(51) Int. Cl. H05K 1/02

(52) U.S. Cl. CPC H05K 1/0265; H05K 2201/0776; H05K 1/0218; H05K 1/0215

(57) ABSTRACT

Embodiments of a printed wiring board configured to inhibit increases in electrical resistance between a ground circuit and a reinforcement member are disclosed. The printed wiring board has a substrate film with a base film and a printed circuit, which printed circuit includes a ground circuit; an adhesive layer formed on the substrate film; and a conductive reinforcement member formed on the adhesive layer. The adhesive layer includes conductive particles. One or more layers of low-melting-point metal is or are provided between the adhesive layer and the substrate film; between the adhesive layer and the reinforcement member; and/or around the conductive particles.

### CROSS-REFERENCE TO RELATED APPLICATIONS

This application is a continuation of U.S. application Ser. No. 16/480,247 filed Jul. 23, 2019, the priority benefit of which is claimed and the contents of which are incorporated by reference. That application is the U.S. National Stage of PCT application PCT/JP2018/004658 filed Feb. 9, 2018, the priority benefit of which is claimed and the contents of which are incorporated by reference. The PCT application, in turn, is based on Japanese application JP 2017-024499 filed Feb. 13, 2017, the priority benefit of which is claimed and the contents of which are incorporated by reference.

### TECHNICAL FIELD

The present invention relates to a printed wiring board.

### BACKGROUND ART

In order to shield electronic components of mobile phones and computers from noise, it has been known that such electronic components are mounted on printed wiring boards including films. In some cases, printed wiring boards are distorted at a mounting site where electronic components are mounted due to bending or the like during use, causing breakage of the electronic components. Thus, in order to prevent breakage of electronic components due to external force such as distortion of a mounting site, generally, a stainless steel conductive reinforcing plate or the like is disposed at a position opposite to the mounting site where the electronic components are mounted (Patent Literatures 1 and 2).

### CITATION LIST

### Patent Literature

Patent Literature 1: JP 2007-189091 A
Patent Literature 2: JP 2009-218443 A

### SUMMARY OF INVENTION

### Technical Problem

Yet, a problem was found that the peel value (force required for removal) of a reinforcement member with respect to a conductive adhesive reduces in a high temperature high humidity environment. Thus, in such an environment, the reinforcement member may come off from the conductive adhesive, or shielding properties may decrease due to a decrease in adhesive force between the conductive adhesive and the reinforcement member, and an increase in electrical resistance.

There was also room for improvement in suppressing an increase in electrical resistance.

The present invention was made to solve the above problems. An aim of the present invention is to provide a printed wiring board in which the electrical resistance between a ground circuit and a reinforcement member of the printed wiring board is suppressed.

### Solution to Problem

Specifically, the printed wiring board of the present invention includes: a substrate film including a base film and a printed circuit including a ground circuit; an adhesive layer formed on the substrate film; and a conductive reinforcement member formed on the adhesive layer, wherein the adhesive layer contains conductive particles and an adhesive resin, the conductive particles are at least one selected from the group consisting of first conductive particles each including a non-conductive core particle and a first low-melting-point metal layer formed on the non-conductive core particle, intrinsically conductive second conductive particles, and third conductive particles each including a conductive core particle and a first low-melting-point metal layer formed on the conductive core particle; a second low-melting-point metal layer is formed between the substrate film and the adhesive layer, or the substrate film is in direct contact with the adhesive layer; a third low-melting-point metal layer is formed between the adhesive layer and the reinforcement member, or the adhesive layer is in direct contact with the reinforcement member; the printed wiring board includes at least one low-melting-point metal layer selected from the group consisting of the first low-melting-point metal layer, the second low-melting-point metal layer, and the third low-melting-point metal layer; and the ground circuit is electrically connected to the reinforcement member via at least one low-melting-point metal layer selected from the group consisting of the first low-melting-point metal layer, the second low-melting-point metal layer, and the third low-melting-point metal layer.

The printed wiring board of the present invention includes at least one low-melting-point metal layer selected from the group consisting of the first low-melting-point metal layer, the second low-melting-point metal layer, and the third low-melting-point metal layer, and the ground circuit is electrically connected to the reinforcement member via at least one low-melting-point metal layer selected from the group consisting of the first low-melting-point metal layer, the second low-melting-point metal layer, and the third low-melting-point metal layer.

When at least one low-melting-point metal layer is formed as described above, it is possible to improve the adhesion between the conductive particles, adhesion between the substrate film and the adhesive layer, and adhesion between the adhesive layer and the reinforcement member.

Thus, an increase in electrical resistance resulting from shift in contact can be suppressed.

In the printed wiring board of the present invention, preferably, the conductive particles have an average particle size of 1 to 200 μm.

The conductive particles having an average particle size less than 1 μm are small, and are thus less likely to be uniformly dispersed in the adhesive layer.

The conductive particles having an average particle size more than 200 μm have a small specific surface area, and are thus less likely to contact each other. As a result, the electrical resistance of the adhesive layer is likely to increase.

In the printed wiring board of the present invention, preferably, the first low-melting-point metal layer is formed from a metal having a melting point of 300° C. or lower.

When the first low-melting-point metal layer is formed from a metal having a melting point of 300° C. or lower, the first low-melting-point metal layer is easily softened, suitably improving the adhesion between the first conductive particles.

In the production of the printed wiring board of the present invention, the first low-melting-point metal layer is first heated and softened. The heating temperature will be high when the first low-melting-point metal layer is formed from a metal having a melting point higher than 300° C., making the printed wiring board susceptible to thermal damage.

In the printed wiring board of the present invention, preferably, the first low-melting-point metal layer has a thickness of 0.1 to 50 μm.

When the first low-melting-point metal layer has a thickness less than 0.1 μm, the amount of the metal constituting the first low-melting-point metal layer is small, so that the adhesion between the first conductive particles is less likely to improve.

The first low-melting-point metal layer having a thickness more than 50 μm is thick, and is thus likely to significantly change its shape when heated. Thus, the shape of the printed wiring board is likely to be deformed.

In the printed wiring board of the present invention, preferably, the first low-melting-point metal layer contains a flux.

The presence of the flux in the first low-melting-point metal layer facilitates improving the adhesion between the conductive particles when the metal constituting the first low-melting-point metal layer is softened.

In the printed wiring board of the present invention, preferably, the second low-melting-point metal layer is formed from a metal having a melting point of 300° C. or lower.

When the second low-melting-point metal layer is formed from a metal having a melting point of 300° C. or lower, the second low-melting-point metal layer is easily softened, suitably improving the adhesion between the substrate film and the adhesive layer.

In the production of the printed wiring board of the present invention, the second low-melting-point metal layer is first heated and softened. The heating temperature will be high when the second low-melting-point metal layer is formed from a metal having a melting point higher than 300° C., making the printed wiring board susceptible to thermal damage.

In the printed wiring board of the present invention, preferably, the second low-melting-point metal layer has a thickness of 0.1 to 50 μm.

When the second low-melting-point metal layer has a thickness less than 0.1 μm, the amount of the metal constituting second low-melting-point metal layer is small, so that the adhesion between the substrate film and the adhesive layer is less likely to improve.

The second low-melting-point metal layer having a thickness more than 50 μm is thick, and is thus likely to significantly change its shape when heated. Thus, the shape of the printed wiring board is likely to be deformed.

In the printed wiring board of the present invention, preferably, the second low-melting-point metal layer contains a flux.

The presence of the flux in the second low-melting-point metal layer facilitates improving the adhesion between the substrate film and the adhesive layer when the metal constituting the second low-melting-point metal layer is softened.

In the printed wiring board of the present invention, preferably, the third low-melting-point metal layer is formed from a metal having a melting point of 300° C. or lower.

When the third low-melting-point metal layer is formed from a metal having a melting point of 300° C. or lower, the third low-melting-point metal layer is easily softened, suitably improving the adhesion between the adhesive layer and the reinforcement member.

In the production of the printed wiring board of the present invention, the third low-melting-point metal layer is first heated and softened. The heating temperature will be high when the third low-melting-point metal layer is formed from a metal having a melting point higher than 300° C., making the printed wiring board susceptible to thermal damage.

In the printed wiring board of the present invention, preferably, the third low-melting-point metal layer has a thickness of 0.1 to 50 μm.

When the third low-melting-point metal layer has a thickness less than 0.1 μm, the amount of the metal constituting the third low-melting-point metal layer is small, so that the adhesion between the adhesive layer and the reinforcement member is less likely to improve.

The third low-melting-point metal layer having a thickness more than 50 μm is thick, and is thus likely to significantly change its shape when heated. Thus, the shape of the printed wiring board is likely to be deformed.

In the printed wiring board of the present invention, preferably, the third low-melting-point metal layer contains a flux.

The presence of the flux in the third low-melting-point metal layer facilitates improving the adhesion between the adhesive layer and the reinforcement member when the metal constituting the third low-melting-point metal layer is softened.

### Advantageous Effects of Invention

In the printed wiring board of the present invention, the conductive particles are at least one selected from the group consisting of the first conductive particles each including a non-conductive core particle and the first low-melting-point metal layer formed on the non-conductive core particle, the intrinsically conductive second conductive particles, and the third conductive particles each including a conductive core particle and a first low-melting-point metal layer formed on the conductive core particle.

In the printed wiring board of the present invention, the second low-melting-point metal layer is formed between the substrate film and the adhesive layer, or the substrate film is in direct contact with the adhesive layer.

In the printed wiring board of the present invention, the third low-melting-point metal layer is formed between the adhesive layer and the reinforcement member, or the adhesive layer is in direct contact with the reinforcement member.

The printed wiring board of the present invention includes at least one low-melting-point metal layer selected from the group consisting of the first low-melting-point metal layer, the second low-melting-point metal layer, and the third low-melting-point metal layer. The ground circuit is electrically connected to the reinforcement member via at least one low-melting-point metal layer selected from the group consisting of the first low-melting-point metal layer, the second low-melting-point metal layer, and the third low-melting-point metal layer.

Owing to the low-melting-point metal layer, it is possible to improve the adhesion between the conductive particles, adhesion between the substrate film and the adhesive layer, and adhesion between the adhesive layer and the reinforcement member.

Thus, an increase in electrical resistance resulting from shift in contact can be suppressed.

### BRIEF DESCRIPTION OF DRAWINGS

FIG. 1 is a cross-sectional view schematically showing an exemplary printed wiring board of the present invention.

FIG. 2 is a cross-sectional view schematically showing an exemplary printed wiring board of the present invention.

FIG. 3 is a cross-sectional view schematically showing an exemplary printed wiring board of the present invention.

FIG. 4 is a cross-sectional view schematically showing an exemplary printed wiring board of the present invention.

FIGS. 5A and 5B are views schematically showing an exemplary conductive particle preparing step of a method of producing a printed wiring board of the present invention.

FIG. 6 is a view schematically showing an exemplary adhesive layer paste producing step of the method of producing a printed wiring board of the present invention.

FIGS. 7A and 7B are views schematically showing an exemplary adhesive layer forming step of the method of producing a printed wiring board of the present invention.

FIG. 8 is a view schematically showing an exemplary reinforcement member disposing step of the method of producing a printed wiring board of the present invention.

FIG. 9 is a view schematically showing an exemplary heating step of the method of producing a printed wiring board of the present invention.

FIG. 10 is a cross-sectional view schematically showing an exemplary printed wiring board of the present invention.

FIG. 11 is a cross-sectional view schematically showing an exemplary printed wiring board of the present invention.

FIG. 12 is a cross-sectional view schematically showing an exemplary printed wiring board of the present invention.

FIG. 13 is a cross-sectional view schematically showing an exemplary printed wiring board of the present invention.

FIG. 14 is a cross-sectional view schematically showing an exemplary printed wiring board of the present invention.

FIG. 15 is a cross-sectional view schematically showing an exemplary printed wiring board of the present invention.

FIG. 16 is a cross-sectional view schematically showing an exemplary printed wiring board of the present invention.

A shield film of the present invention is specifically described below. However, the present invention is not limited to the following embodiments, and can be appropriately modified without changing the gist of the invention.

First, a description is given on an embodiment of the printed wiring board of the present invention in which the conductive particles are first conductive particles each including a non-conductive core particle and a first low-melting-point metal layer formed on the non-conductive core particle.

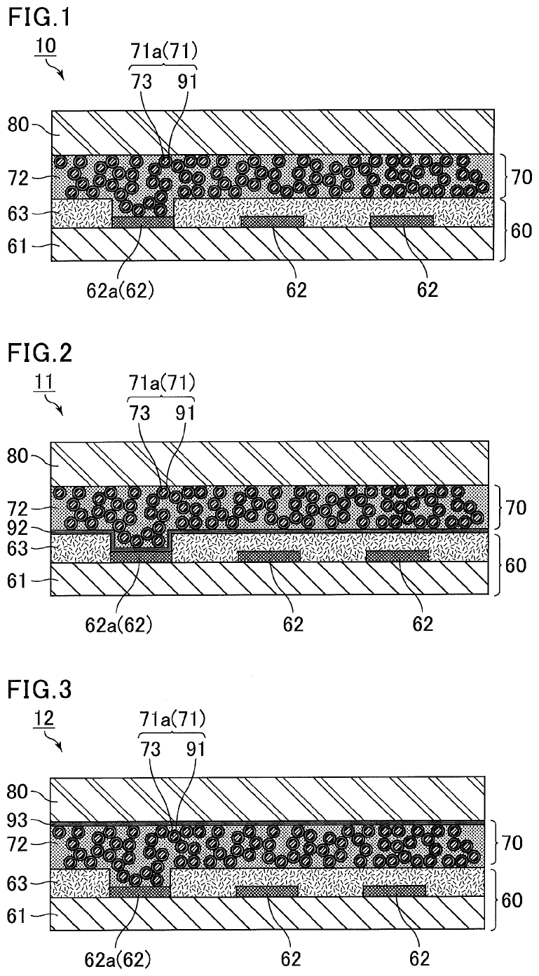

FIG. 1 is a cross-sectional view schematically showing an exemplary printed wiring board of the present invention.

As shown in FIG. 1, a printed wiring board 10 includes: a substrate film 60 sequentially including a base film 61, a printed circuit 62 including a ground circuit 62a, and an insulating film 63; an adhesive layer 70 formed on the substrate film 60; and a conductive reinforcement member 80 formed on the adhesive layer 70.

The adhesive layer 70 includes conductive particles 71 and an adhesive resin 72.

The conductive particles 71 are first conductive particles 71a each including a non-conductive core particle 73 and a first low-melting-point metal layer 91 formed on the non-conductive core particle.

The first conductive particles 71a are connected to each other via the first low-melting-point metal layers 91.

Thus, the ground circuit 62a is electrically connected to the reinforcement member 80 via the first low-melting-point metal layers 91 of the first conductive particles 71a.

First, the substrate film 60 of the printed wiring board is described.

The base film 61 and the insulating film 63 constituting the substrate film 60 may be formed from any material, but are preferably formed from an engineering plastic. Examples of the engineering plastic include resins such as polyethylene terephthalate, polypropylene, crosslinked polyethylene, polyester, polybenzimidazole, polyimide, polyamide-imide, polyetherimide, and polyphenylene sulfide.

Of these engineering plastic films, a polyphenylene sulfide film is preferred when flame retardancy is required, and a polyimide film is preferred when heat resistance is required. Preferably, the base film 61 has a thickness of 10 to 40 μm, and the insulating film 63 has a thickness of 10 to 30 μm.

For contact between the ground circuit 62a and the adhesive layer 70, the insulating film 63 includes a hole 63a formed therein to expose a portion of the ground circuit 62a.

The hole 63a may be formed by any conventional method such as laser processing.

Next, the adhesive layer 70 of the printed wiring board 10 is described.

The thickness of the adhesive layer 70 is not limited, and is preferably determined according to the use of the printed wiring board 10. The thickness of the adhesive layer 70 may be 5 to 50 μm, for example.

The adhesive layer 70 of the printed wiring board 10 contains the first conductive particles 71a and the adhesive resin 72.

The adhesive resin 72 may be any resin, but it is preferably an acrylic resin, an epoxy resin, a silicone resin, a thermoplastic elastomer resin, a rubber-based resin, a polyester resin, a urethane resin, or the like.

The adhesive layer 72 may contain a tackifier such as a fatty acid hydrocarbon resin, a C5/C9 mixture resin, rosin, a rosin derivative, a terpene resin, an aromatic hydrocarbon resin, or a thermally reactive resin. The presence of any of these tackifiers can improve viscosity of the adhesive layer 72.

As described above, each first conductive particle 71a contains the non-conductive core particle 73. For example, the core particles 73 can be formed from a thermosetting resin such as an epoxy resin, a phenolic resin, a urethane resin, a melamine resin, an alkyd resin, an acrylic resin, or a styrene resin.

Preferably, the first conductive particles 71a have an average particle size of 1 to 200 μm.

The first conductive particles 71a having an average particle size less than 1 μm are small, and are thus less likely to be uniformly dispersed in the adhesive layer 70.

The first conductive particles 71a having an average particle size more than 200 μm have a small specific surface area, and are thus less likely to contact each other. As a result, the electrical resistance of the adhesive layer 70 is likely to increase.

In the printed wiring board 10, the first low-melting-point metal layer 91 is formed on the surface of the core particle 73.

Thus, the adhesive layer 70 including the first conductive particles 71a each including the core particle 73 and the first low-melting-point metal layer 91 formed on the surface of the core particle can function as a conductive adhesive layer.

The low-melting-point metal layer 91 can also improve the adhesion between the first conductive particles 71a.

Thus, an increase in electrical resistance resulting from shift in contact between the first conductive particles 71a can be suppressed.

In the printed wiring board 10, preferably, the first low-melting-point metal layer 91 is formed from a metal having a melting point of 300° C. or lower.

When the first low-melting-point metal layer 91 is formed from a metal having a melting point of 300° C. or lower, the first low-melting-point metal layer 91 is easily softened, suitably improving the adhesion between the first conductive particles 71a.

In the production of the printed wiring board 10, the first low-melting-point metal layer 91 is first heated and softened. The heating temperature will be high when the first low-melting-point metal layer 91 is formed from a metal having a melting point higher than 300° C., making the printed wiring board 10 susceptible to thermal damage.

In the printed wiring board 10, the first low-melting-point metal layer 91 is not limited, but preferably contains at least one selected from the group consisting of indium, tin, lead, and bismuth.

These metals have melting points and conductivity suitable to form the first low-melting-point metal layer 91.

In the printed wiring board 10, preferably, the first low-melting-point metal layer 91 has a thickness of 0.1 to 50 μm.

When the first low-melting-point metal layer 91 has a thickness less than 0.1 μm, the amount of the metal constituting the first low-melting-point metal layer 91 is small, so that the adhesion between the first conductive particles 71a is less likely to improve.

The first low-melting-point metal layer 91 having a thickness more than 50 μm is thick, and is thus likely to significantly change its shape when heated. Thus, the shape of the printed wiring board 10 is likely to be deformed.

In the printed wiring board 10, the first low-melting-point metal layer 91 content in the first conductive particle 71a is preferably 1 wt % or more, more preferably 5 to 50 wt %, still more preferably 10 to 30 wt %.

When the first low-melting-point metal layer 91 content is less than 1 wt %, the amount of the metal constituting the first low-melting-point metal layer 91 is small, so that the adhesion between the first conductive particles 71a is less likely to improve.

The first low-melting-point metal layer 91 is thick when its content is more than 50 wt %, and is thus likely to significantly change its shape when heated. Thus, the shape of the printed wiring board 10 is likely to be deformed.

In the printed wiring board 10, preferably, the first low-melting-point metal layer 91 contains a flux.

The presence of the flux in the first low-melting-point metal layer 91 facilitates improving the adhesion between the first conductive particles 71a when the metal constituting the first low-melting-point metal layer 91 is softened.

Any known flux can be used. Examples include polyvalent carboxylic acids, lactic acid, citric acid, oleic acid, stearic acid, glutamic acid, benzoic acid, glycerol, and rosin.

In the printed wiring board 10, preferably, the weight ratio of the first conductive particles 71a to the adhesive resin 72 (first conductive particles:adhesive resin) is 30:70 to 70:30.

When the weight ratio of the first conductive particles 71a to the adhesive resin 72 is as described above, the first conductive particles 71a are likely to contact each other.

Thus, an increase in electrical resistance resulting from shift in contact between the first conductive particles 71a can be suppressed.

Next, the reinforcement member 80 of the printed wiring board 10 is described.

The material of the reinforcement member 80 is not limited, but it is preferably stainless steel, nickel, copper, silver, tin, gold, palladium, aluminum, chromium, titanium, zinc, an alloy of these, or the like.

These materials have suitable strength and conductivity for use as reinforcement members.

The reinforcement member 80 may include a nickel layer or a noble metal layer formed on the surface.

When a nickel layer is formed on the surface of the reinforcement member 80, the degree of gloss of the nickel layer is preferably 500 or less, more preferably 460 or less.

When the degree of gloss of the nickel layer is 500 or less, the surface area of the adhesive surface between the reinforcement member 80 and the adhesive layer 70 can be increased, and the adhesive force can thus be maintained at high levels. More preferably, the nickel layer is dull, without containing a glossing agent.

The printed wiring board of the present invention may have a configuration in which a second low-melting-point metal layer is formed between the substrate film and the adhesive layer, and a third low-melting-point metal layer is formed between the adhesive layer and the reinforcement member.

Such an embodiment is described with reference to the drawings.

FIGS. 2 to 4 each schematically show a cross-sectional view of an exemplary printed wiring board of the present invention.

As shown in FIG. 2, in a printed wiring board 11, a second low-melting-point metal layer 92 is formed between the substrate film 60 and the adhesive layer 70, and the adhesive layer 70 is in direct contact with the reinforcement member 80.

As shown in FIG. 3, in a printed wiring board 12, the substrate film 60 is in direct contact with the adhesive layer 70, and a third low-melting-point metal layer 93 is formed between the adhesive layer 70 and the reinforcement member 80.

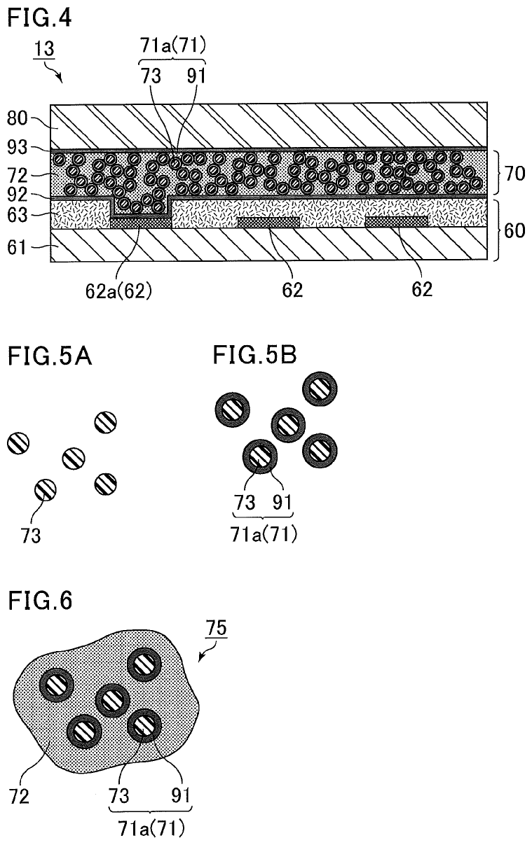

As shown in FIG. 4, in a printed wiring board 13, the second low-melting-point metal layer 92 is formed between the substrate film 60 and the adhesive layer 70, and the third low-melting-point metal layer 93 is formed between the adhesive layer 70 and the reinforcement member 80.

As shown in FIG. 3 and FIG. 5, the second low-melting-point metal layer 92 may cover the entire surface of the substrate film 60 or may cover only a portion of the ground circuit 62a.

As shown in FIG. 4 and FIG. 5, the third low-melting-point metal layer 93 may cover the entire surface of the reinforcement member 80 or may cover only a portion of the reinforcement member 80.

When the printed wiring board of the present invention includes the second low-melting-point metal layer 92 as described above, preferably, the second low-melting-point metal layer 92 has the following features.

The second low-melting-point metal layer 92 is not limited, but preferably contains at least one selected from the group consisting of indium, tin, lead, and bismuth.

These metals have melting points and conductivity suitable to form the second low-melting-point metal layer 92.

Preferably, the second low-melting-point metal layer 92 is formed from a metal having a melting point of 300° C. or lower.

When the second low-melting-point metal layer 92 is formed from a metal having a melting point of 300° C. or lower, the second low-melting-point metal layer 92 is easily softened, suitably improving the adhesion between the substrate film 60 and the adhesive layer 70.

In the production of the printed wiring board of the present invention, the second low-melting-point metal layer 92 is first heated and softened. The heating temperature will be high when the second low-melting-point metal layer 92 is formed from a metal having a melting point higher than 300° C., making the printed wiring board of the present invention susceptible to thermal damage.

Preferably, the second low-melting-point metal layer 92 has a thickness of 0.1 to 50 μm.

When the second low-melting-point metal layer 92 has a thickness less than 0.1 μm, the amount of the metal constituting the second low-melting-point metal layer 92 is small, so that the adhesion between the substrate film 60 and the adhesive layer 70 is less likely to improve.

The second low-melting-point metal layer 92 having a thickness more than 50 μm is thick, and is thus likely to significantly change its shape when heated. Thus, the shape of the printed wiring board is likely to be deformed.

Preferably, the second low-melting-point metal layer 92 contains a flux.

The presence of the flux in the second low-melting-point metal layer 92 facilitates improving the adhesion between the substrate film 60 and the adhesive layer 70 when the metal constituting the second low-melting-point metal layer 92 is softened.

Any known flux can be used. Examples include polyvalent carboxylic acids, lactic acid, citric acid, oleic acid, stearic acid, glutamic acid, benzoic acid, glycerol, and rosin.

When the printed wiring board of the present invention includes the third low-melting-point metal layer 93, preferably, the third low-melting-point metal layer 93 has the following features.

The third low-melting-point metal layer 93 is not limited, but preferably contains at least one selected from the group consisting of indium, tin, lead, and bismuth.

These metals have melting points and conductivity suitable to form the second low-melting-point metal layer 93.

Preferably, the third low-melting-point metal layer 93 is formed from a metal having a melting point of 300° C. or lower.

When the third low-melting-point metal layer 93 is formed from a metal having a melting point of 300° C. or lower, the third low-melting-point metal layer 93 is easily softened, suitably improving the adhesion between the adhesive layer 70 and the reinforcement member 80.

In the production of the printed wiring board of the present invention, the third low-melting-point metal layer 93 is first heated and softened. The heating temperature will be high when the third low-melting-point metal layer 93 is formed from a metal having a melting point higher than 300° C., making the printed wiring board susceptible to thermal damage.

Preferably, the third low-melting-point metal layer 93 has a thickness of 0.1 to 50 μm.

When the third low-melting-point metal layer 93 has a thickness less than 0.1 μm, the amount of the metal constituting the third low-melting-point metal layer 93 is small, so that the adhesion between the adhesive layer 70 and the reinforcement member 80 is less likely to improve.

The third low-melting-point metal layer 93 having a thickness more than 50 μm is thick, and is thus likely to significantly change its shape when heated. Thus, the shape of the printed wiring board is likely to be deformed.

Preferably, the third low-melting-point metal layer 93 contains a flux.

The presence of the flux in the third low-melting-point metal layer 93 facilitates improving the adhesion between the adhesive layer 70 and the reinforcement member 80 when the metal constituting the third low-melting-point metal layer 93 is softened.

Any known flux can be used. Examples include polyvalent carboxylic acids, lactic acid, citric acid, oleic acid, stearic acid, glutamic acid, benzoic acid, glycerol, and rosin.

Next, the method of producing the printed wiring board 10 is described with reference to the drawings.

FIGS. 5A and 5B are views schematically showing an exemplary conductive particle preparing step of the method of producing a printed wiring board of the present invention.

FIG. 6 is a view schematically showing an exemplary adhesive layer paste producing step of the method of producing a printed wiring board of the present invention.

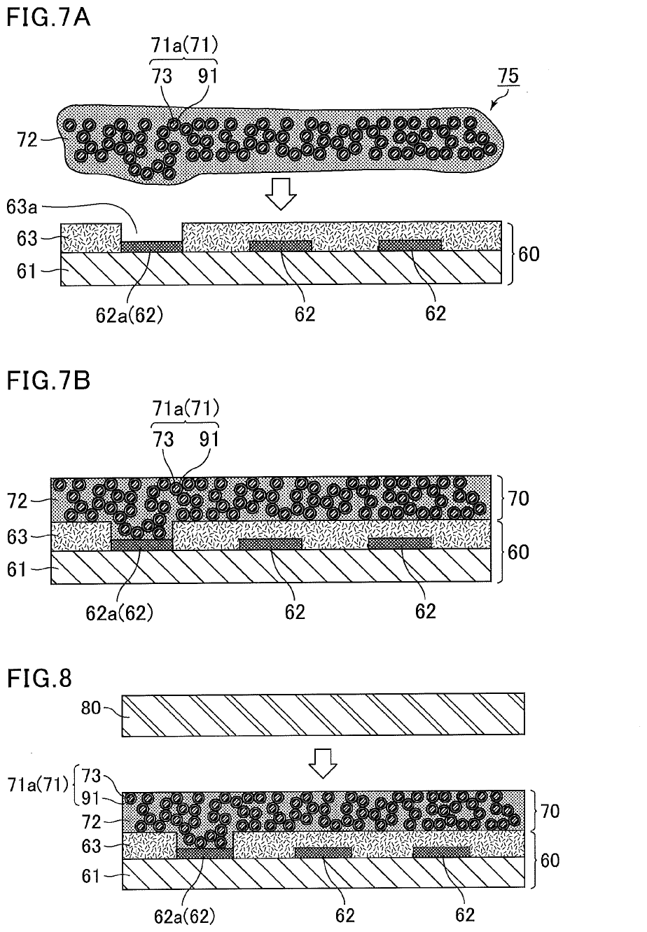

FIGS. 7A and 7B are views schematically showing an exemplary adhesive layer forming step of the method of producing a printed wiring board of the present invention.

FIG. 8 is a view schematically showing an exemplary reinforcement member disposing step of the method of producing a printed wiring board of the present invention.

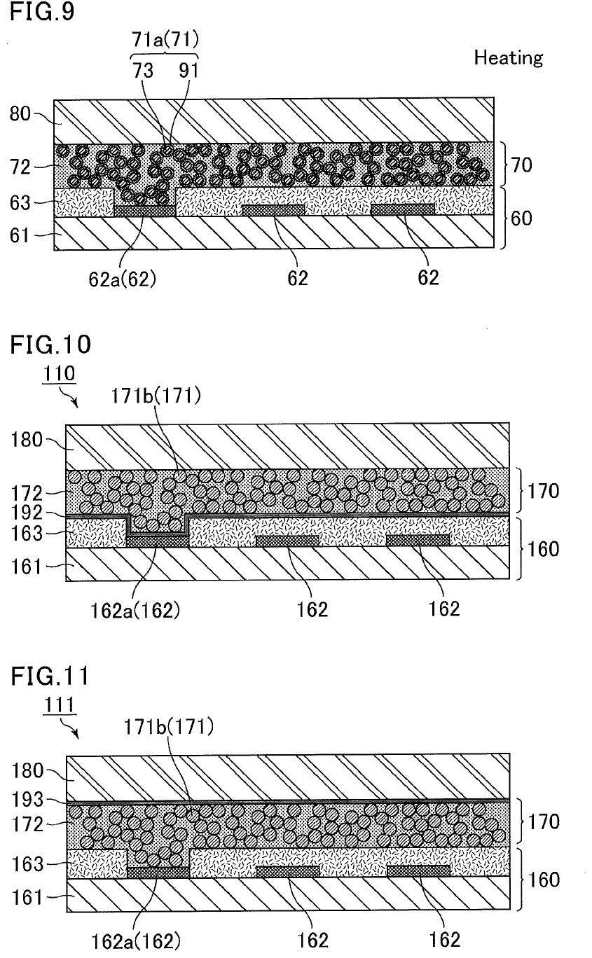

FIG. 9 is a view schematically showing an exemplary heating step of the method of producing a printed wiring board of the present invention.

Examples of the method of producing the printed wiring board 10 include a method that includes (1) a conductive particle preparing step, (2) an adhesive layer paste producing step, (3) an adhesive layer forming step, (4) a reinforcement member disposing step, and (5) a heating step.

### (1) Conductive Particle Preparing Step

First, as shown in FIG. 5A, the non-conductive core particles 73 are provided.

The non-conductive core particles 73 can be formed from a thermosetting resin such as an epoxy resin, a phenolic resin, a urethane resin, a melamine resin, an alkyd resin, an acrylic resin, or a styrene resin.

Next, as shown in FIG. 5B, the first low-melting-point metal layer 91 is formed on the surface of the non-conductive core particle 73. The first low-melting-point metal layer 91 can be formed on the surface of the non-conductive core particle 73 by a method such as electroless plating, electrolytic plating, or vacuum deposition.

Preferred metals to produce the first low-melting-point metal layer 91 are as described above, and a description thereof is thus omitted.

In this manner, the first conductive particles 71a each including the core particle 73 and the first low-melting-point metal layer 91 formed on the surface of the core particle can be prepared.

### (2) Adhesive Layer Paste Producing Step

As shown in FIG. 6, the first conductive particles 71a and the adhesive resin 72 are mixed together to produce an adhesive layer paste 75.

Preferably, the weight ratio of the first conductive particles 71a to the adhesive resin 72 (first conductive particles:adhesive resin) is 30:70 to 70:30.

When the weight ratio of the first conductive particles 71a to the adhesive resin 72 is as described above, the first conductive particles 71a are likely to contact each other.

Thus, an increase in electrical resistance resulting from shift in contact between the first conductive particles 71a can be suppressed.

### (3) Adhesive Layer Forming Step

The substrate film 60 is provided by sequentially disposing the printed circuit 62 including the ground circuit 62a and the insulating film 63 on the base film 61. Then, the hole 63a is formed to expose a portion of the ground circuit 62a. The hole 63a may be formed by any conventional method such as laser processing.

Next, the adhesive layer paste 75 is applied to the insulating layer 63 of the substrate film 60 as shown in FIG. 7A, and the adhesive layer 70 is formed as shown in FIG. 7B. At this time, the adhesive layer 70 fills the hole 63a of the insulating layer 63, and the ground circuit 62a and the adhesive layer 70 come into contact with each other.

### (4) Reinforcement Member Disposing Step

As shown in FIG. 8, the reinforcement member 80 is disposed on the adhesive layer 70. Preferably, the size and position of the reinforcement member 80 to be disposed is adjusted according to the use or the like of the printed wiring board to be produced.

Thus, a printed wiring board including a substrate film, an adhesive layer formed on the substrate film, and a conductive reinforcement member formed on the adhesive layer can be produced.

### (5) Heating Step

As shown in FIG. 9, the produced printed wiring board is heated, whereby the first low-melting-point metal layer is softened. This allows the first conductive particles to be connected to each other, improving the adhesion between the first conductive particles.

The heating temperature is not limited as long as it is a temperature at which the first low-melting-point metal layer is softened, but it is preferably 100° C. to 300° C.

The heating step may be performed in a step of mounting components on the shielded printed wiring board. For example, when solder is used to mount components, a reflow soldering step will be involved. The low-melting-point metal layer may be softened by heat of reflow soldering in the reflow soldering step. In this case, the heating step and the mounting of components will be performed simultaneously.

The printed wiring board 10 can be produced through the above steps.

When forming the second low-melting-point metal layer 92 between the substrate film 60 and the adhesive layer 70 and/or forming the third low-melting-point metal layer 93 between the adhesive layer 70 and the reinforcement member 80 as in the printed wiring board 11, the printed wiring board 12, and/or the printed wiring board 13 shown respectively in FIG. 2 to FIG. 4, the method may include forming the second low-melting-point metal layer 92 on the substrate film 60 and/or forming the third low-melting-point metal layer 93 on the adhesive layer 70 in the adhesive layer forming step (3) or the reinforcement member disposing step (4).

These low-melting-point metal layers may be formed by a method such as plating.

The printed wiring board of the present invention may include an electromagnetic wave shielding film to shield the printed wiring board from electromagnetic waves.

Next, a description is given on an embodiment of the printed wiring board of the present invention in which the conductive particles are intrinsically conductive second conductive particles.

FIG. 10 is a cross-sectional view schematically showing an exemplary printed wiring board of the present invention.

As shown in FIG. 10, a printed wiring board 110 includes: a substrate film 160 sequentially including a base film 161, a printed circuit 162 including a ground circuit 162a, and an insulating film 163; an adhesive layer 170 formed on the substrate film 160, and a conductive reinforcement member 180 formed on the adhesive layer 170.

The adhesive layer 170 contains conductive particles 171 and an adhesive resin 172, and the conductive particles 171 are intrinsically conductive second conductive particles 171b.

A second low-melting-point metal layer 192 is formed between the substrate film 160 and the adhesive layer 170.

Thus, the ground circuit 162a is electrically connected to the reinforcement member 180 via the second low-melting-point metal layer 192.

The adhesive layer 170 of the printed wiring board 110 is described.

The thickness of the adhesive layer 170 is not limited, and is preferably determined according to the use of the printed wiring board 110. The thickness of the adhesive layer 170 may be 5 to 50 μm, for example.

The adhesive layer 170 of the printed wiring board 110 contains the second conductive particles 171b and the adhesive resin 172.

The adhesive resin 172 may be any resin, but it is preferably an acrylic resin, an epoxy resin, a silicone resin, a thermoplastic elastomer resin, a rubber-based resin, a polyester resin, a urethane resin, or the like.

The adhesive resin 172 may contain a tackifier such as a fatty acid hydrocarbon resin, a C5/C9 mixture resin, rosin, a rosin derivative, a terpene resin, an aromatic series-based hydrocarbon resin, or a thermal-reactive resin. The presence of any of these tackifiers can improve the viscosity of the adhesive resin 172.

In the printed wiring board 110, the second conductive particles 171b are intrinsically conductive. Thus, the adhesive layer 170 can function as a conductive adhesive layer, without a low-melting-point metal layer or the like provided on the surface of the second conductive particle 171b.

In the printed wiring board 110, preferably, the second conductive particles 171b contain at least one selected from the group consisting of copper, aluminum, silver, nickel, nickel-coated copper, nickel-coated silver, silver-coated copper, and silver-coated resin.

Preferably, the second conductive particles 171b have an average particle size of 1 to 200 μm.

The second conductive particles 171b having an average particle size less than 1 μm are small, and are thus less likely to be uniformed dispersed in the adhesive layer 170.

The second conductive particles 171b having an average particle size more than 200 μm have a small specific surface area, and are thus less likely to contact each other. As a result, the electrical resistance of the adhesive layer 170 is likely to increase.

Next, the second low-melting-point metal layer 192 of the printed wiring board 110 is described.

In the printed wiring board 110, the second low-melting-point metal layer 192 is formed between the substrate film 160 and the adhesive layer 170.

This makes it possible to improve the adhesion between the substrate film 160 and the adhesive layer 170.

Thus, an increase in electrical resistance resulting from shift in contact between the substrate film 160 and the adhesive layer 170 can be suppressed.

The second low-melting-point metal layer 192 may cover the entire surface of the substrate film 160 as shown in FIG. 10, or may cover only a portion of the ground circuit 162a.

In the printed wiring board 110, preferably, the second low-melting-point metal layer 192 is formed from a metal having a melting point of 300° C. or lower.

When the second low-melting-point metal layer 192 is formed from a metal having a melting point of 300° C. or lower, the second low-melting-point metal layer is easily softened, suitably improving the adhesion between the substrate film 160 and the adhesive layer 170.

In the production of the printed wiring board 110, the second low-melting-point metal layer 192 is first heated and softened. The heating temperature will be high when the second low-melting-point metal layer 192 is formed from a metal having a melting point higher than 300° C., making the printed wiring board 110 susceptible to thermal damage.

In the printed wiring board 110, the second low-melting-point metal layer 192 is not limited, but preferably contains at least one selected from the group consisting of indium, tin, lead, and bismuth.

These metals have melting points and conductivity suitable to form the second low-melting-point metal layer 192.

In the printed wiring board 110, preferably, the second low-melting-point metal layer 192 has a thickness of 0.1 to 50 μm.

When the second low-melting-point metal layer 192 has a thickness less than 0.1 μm, the amount of the metal constituting the second low-melting-point metal layer 192 is small, so that the adhesion between the substrate film 160 and the adhesive layer 170 is less likely to improve.

The second low-melting-point metal layer 192 having a thickness more than 50 μm is thick, and is thus likely to significantly change its shape when heated. Thus, the shape of the printed wiring board 110 is likely to be deformed.

In the printed wiring board 110, preferably the second low-melting-point metal layer 192 contains a flux.

The presence of the flux in the second low-melting-point metal layer 192 facilitates improving the adhesion between the substrate film 160 and the adhesive layer 170 when the metal constituting the second low-melting-point metal layer 192 is softened.

Any known flux can be used. Examples include polyvalent carboxylic acids, lactic acid, citric acid, oleic acid, stearic acid, glutamic acid, benzoic acid, glycerol, and rosin.

In the printed wiring board 110, preferably, the weight ratio of the second conductive particles 171b to the adhesive resin 172 (second conductive particles:adhesive resin) is 30:70 to 70:30.

When the weight ratio of the second conductive particles 171b to the adhesive resin 172 is as described above, the second conductive particles 171b are likely to contact each other.

Thus, an increase in electrical resistance resulting from shift in contact between the second conductive particles 171b can be suppressed.

In the printed wiring board 110, preferred structures and the like of the substrate film 160 and the reinforcement member 180 are the same as those of the substrate film 60 and the reinforcement member 80 of the printed wiring board 10.

The printed wiring board 110 includes at least one of the second low-melting-point metal layer 192 formed between the substrate film 160 and the adhesive layer 170, or a third low-melting-point metal layer 193 formed between the adhesive layer 170 and the reinforcement member 180.

Such another embodiment of the printed wiring board is described with reference to the drawings.

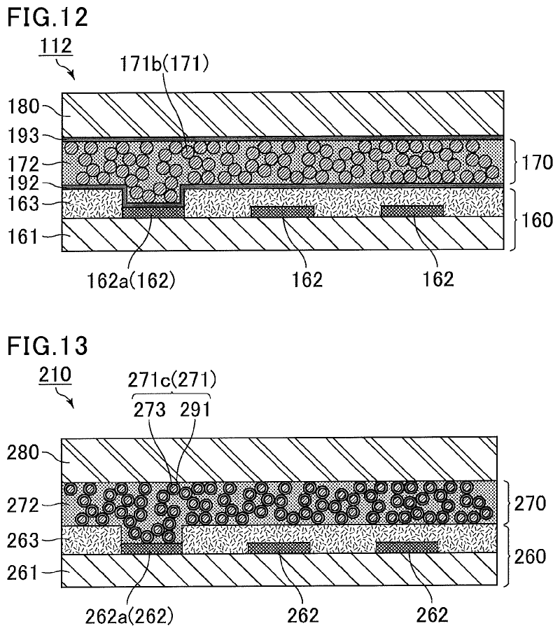

FIG. 11 and FIG. 12 are each a cross-sectional view schematically showing an exemplary printed wiring board of the present invention.

As shown in FIG. 11, in the printed wiring board 111, the conductive particles 171 are the intrinsically conductive second conductive particles 171b; the substrate film 160 is in direct contact with the adhesive layer 170; and the third low-melting-point metal layer 193 is formed between the adhesive layer 170 and the reinforcement member 180.

The third low-melting-point metal layer 193 may cover the entire surface of the reinforcement member 180 as shown in FIG. 11, or may cover only a portion of the reinforcement member 180.

As shown in FIG. 12, in a printed wiring board 112, the conductive particles 171 are the intrinsically conductive second conductive particles 171b; the second low-melting-point metal layer 192 is formed between the substrate film 160 and the adhesive layer 170; and the third low-melting-point metal layer 193 is formed between the adhesive layer 170 and the reinforcement member 180.

When the printed wiring board of the present invention includes the third low-melting-point metal layer 193, preferably, the third low-melting-point metal layer 193 has the following features.

Preferably, the third low-melting-point metal layer 193 is formed from a metal having a melting point of 300° C. or lower.

When the third low-melting-point metal layer 193 is formed from a metal having a melting point of 300° C. or lower, the third low-melting-point metal layer 193 is easily softened, suitably improving the adhesion between the adhesive layer 170 and the reinforcement member 180.

In the production of the printed wiring board of the present invention, the third low-melting-point metal layer 193 is first heated and softened. The heating temperature will be high when the third low-melting-point metal layer 193 is formed from a metal having a melting point higher than 300° C., making the printed wiring board susceptible to thermal damage.

Preferably, the third low-melting-point metal layer 193 has a thickness of 0.1 to 50 μm.

When the third low-melting-point metal layer 193 has a thickness less than 0.1 μm, the amount of the metal constituting the third low-melting-point metal layer 193 is small, so that the adhesion between the adhesive layer 170 and the reinforcement member 180 is less likely to improve.

The third low-melting-point metal layer 193 having a thickness more than 50 μm is thick, and is thus likely to significantly change its shape when heated. Thus, the shape of the printed wiring board is likely to be deformed.

Preferably, the third low-melting-point metal layer 193 contains a flux.

The presence of the flux in the third low-melting-point metal layer 193 facilitates improving the adhesion between the adhesive layer 170 and the reinforcement member 180 when the metal constituting the third low-melting-point metal layer 193 is softened.

The method of producing these printed wiring boards 110 to 112 may be the same as the method of producing the printed wiring board 10, except that the second conductive particles are prepared instead of the first conductive particles in the conductive particle preparing step (1) and the second low-melting-point metal layer is formed on the substrate film or the third low-melting-point metal layer is formed on the adhesive layer in the adhesive layer forming step (3) or the reinforcement member disposing step (4).

These low-melting-point metal layers may be formed by a method such as plating.

Next, a description is given on an embodiment of the printed wiring board of the present invention in which the conductive particles are third conductive particles each including a conductive core particle and a first low-melting-point metal layer formed on the conductive core particle.

FIG. 13 is a cross-sectional view schematically showing an exemplary printed wiring board of the present invention.

As shown in FIG. 13, a printed wiring board 210 includes: a substrate film 260 sequentially including a base film 261, a printed circuit 262 including a ground circuit 262a, and an insulating film 263; an adhesive layer 270 formed on the substrate film 260; and a conductive reinforcement member 280 formed on the adhesive layer 270.

The adhesive layer 270 includes conductive particles 271 and an adhesive resin 272, and the conductive particles 271 are third conductive particles 271c each including a conductive core particle 273 and a first low-melting-point metal layer 291 formed on the conductive core particle.

The third conductive particles 271c are connected to each other via the first low-melting-point metal layers 291.

Thus, the ground circuit 262a is electrically connected to the reinforcement member 280 via the first low-melting-point metal layers 291 of the third conductive particles 271c.

The adhesive layer 270 of the printed wiring board 210 is described.

The thickness of the adhesive layer 270 is not limited, and is preferably determined according to the use of the printed wiring board 210. The thickness of the adhesive layer 270 may be 5 to 50 μm, for example.

The adhesive layer 270 of the printed wiring board 210 includes the third conductive particles 271c and the adhesive resin 272.

The adhesive resin 272 may be any resin, but it is preferably, an acrylic resin, an epoxy resin, a silicone resin, a thermoplastic elastomer resin, a rubber-based resin, a polyester resin, a urethane resin, or the like.

The adhesive resin 272 may contain a tackifier such as a fatty acid hydrocarbon resin, a C5/C9 mixture resin, rosin, a rosin derivative, a terpene resin, an aromatic series-based hydrocarbon resin, or a thermal-reactive resin. The presence of any of these tackifiers can improve the viscosity of the adhesive resin 272.

In the printed wiring board 210, the first low-melting-point metal layer 291 is formed on the surface of the conductive core particle 273.

Thus, the adhesive layer 270 including the third conductive particles 271c each including the core particle 273 and the first low-melting-point metal layer 291 formed on the surface of the core particle can function as a conductive adhesive layer.

Since the core particles 273 are conductive, even when the third conductive particle 271c with its core particle 273 exposed comes into contact with another third conductive particle 271c at the exposed portion, a current still flows between these third conductive particles 271c. Thus, it is possible to ensure conductivity even when the core particles 273 are exposed due to friction or the like.

In the printed wiring board 210, the third conductive particles 271c preferably contain at least one selected from the group consisting of copper, aluminum, silver, nickel, nickel-coated copper, nickel-coated silver, silver-coated copper, and silver-coated resin.

Preferably, the third conductive particles 271c have an average particle size of 1 to 200 μm.

The third conductive particles 271c having an average particle size less than 1 μm are small, and are thus less likely to be uniformly dispersed in the adhesive layer 270.

The third conductive particles 271c having an average particle size more than 200 μm have a small specific surface area, and are thus less likely to contact each other. As a result, the electrical resistance of the adhesive layer 270 is likely to increase.

In the printed wiring board 210, preferably, the first low-melting-point metal layer 291 is formed from a metal having a melting point of 300° C. or lower.

When the first low-melting-point metal layer 291 is formed from a metal having a melting point of 300° C. or lower, the first low-melting-point metal layer 291 is easily softened, suitably improving the adhesion between the third conductive particles 271c.

In the production of the printed wiring board 210, the first low-melting-point metal layer 291 is first heated and softened. The heating temperature will be high when the first low-melting-point metal layer 291 is formed from a metal having a melting point higher than 300° C., making the printed wiring board 210 susceptible to thermal damage.

In the printed wiring board 210, the first low-melting-point metal layer 291 is not limited, but preferably contains at least one selected from the group consisting of indium, tin, lead, and bismuth.

These metals have melting points and conductivity suitable to form the first low-melting-point metal layer 291.

When the first low-melting-point metal layer 291 is formed from tin, the first low-melting-point metal layer 291 and the metal constituting the core particle 273 may form an alloy. Thus, preferably, a nickel layer is formed between the core particle 273 and the first low-melting-point metal layer 291.

The nickel layer, when formed between the core particle 273 and the first low-melting-point metal layer 291, can prevent the formation of such an alloy. As a result, the third conductive particles 271c can efficiently adhere to each other. Thus, it is possible to reduce the amount of tin used in the first low-melting-point metal layer 291.

In the printed wiring board 210, preferably, the first low-melting-point metal layer 291 has a thickness of 0.1 to 50 μm.

When the first low-melting-point metal layer 291 has a thickness less than 0.1 μm, the amount of the metal constituting the first low-melting-point metal layer 291 is small, so that the adhesion between the third conductive particles 271c is less likely to improve.

The first low-melting-point metal layer 291 having a thickness more than 50 μm is thick, and is thus likely to significantly change its shape when heated. Thus, the shape of the printed wiring board 210 is likely to be deformed.

In the printed wiring board 210, the first low-melting-point metal layer 291 content in a first conductive particle 271a is preferably 1 wt % or more, more preferably 5 to 50 wt %, still more preferably 10 to 30 wt %.

When the first low-melting-point metal layer 291 content is less than 1 wt %, the amount of the metal constituting the first low-melting-point metal layer 291 is small, so that the adhesion between the first conductive particles 271a is less likely to improve.

The first low-melting-point metal layer 291 is thick when its content is more than 50 wt %, and is thus likely to significantly change its shape when heated. Thus, the shape of the printed wiring board 210 is likely to be deformed.

In the printed wiring board 210, preferably, the first low-melting-point metal layer 291 contains a flux.

The presence of the flux in the first low-melting-point metal layer 291 facilitates improving the adhesion between the third conductive particles 271c when the metal constituting the first low-melting-point metal layer 291 is softened.

Any known flux can be used. Examples include polyvalent carboxylic acids, lactic acid, citric acid, oleic acid, stearic acid, glutamic acid, benzoic acid, glycerol, and rosin.

In the printed wiring board 210, preferably, the weight ratio of the third conductive particles 271c to the adhesive resin 272 (third conductive particles:adhesive resin) is =30:70 to 70:30.

When the weight ratio of the third conductive particles 271a to the adhesive resin 272 is as described above, the third conductive particles 271a are likely to contact each other.

Thus, an increase in electrical resistance resulting from shift in contact between the third conductive particles 271a can be suppressed.

In the printed wiring board 210, preferred structures and the like of the substrate film 260 and the reinforcement member 280 are the same as those of the substrate film 60 and the reinforcement member 80 of the printed wiring board 10.

The printed wiring board of the present invention may have a configuration in which the second low-melting-point metal layer is formed between the substrate film and the adhesive layer, and the third low-melting-point metal layer is formed between the adhesive layer and the reinforcement member.

Such an embodiment is described with reference to the drawings.

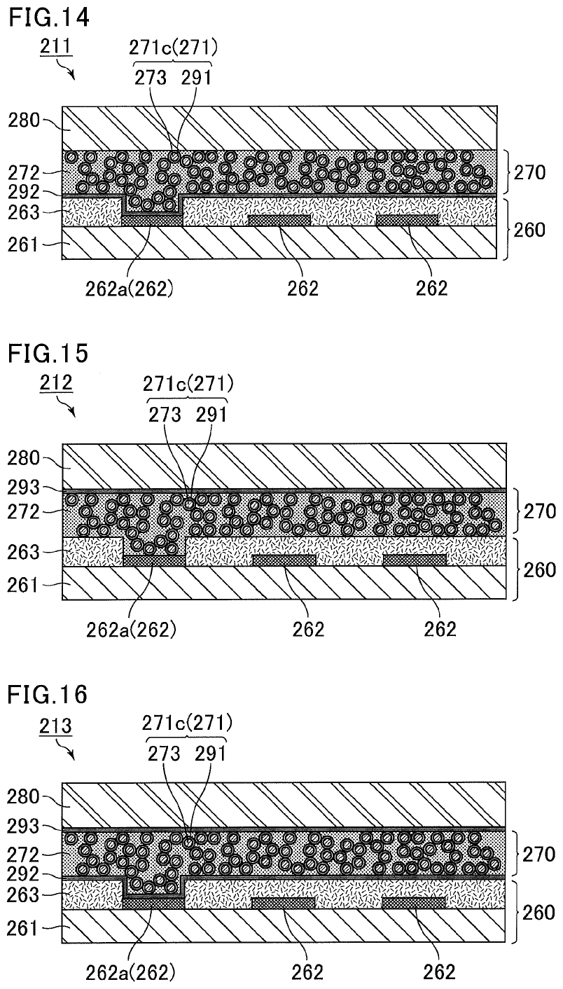

FIG. 14 to FIG. 16 are each a cross-sectional view schematically showing an exemplary printed wiring board of the present invention.

As shown in FIG. 14, in the printed wiring board 211, the third conductive particle 271c includes the first low-melting-point metal layer 291 formed on its periphery; the second low-melting-point metal layer 292 is formed between the substrate film 260 and the adhesive layer 270; and the adhesive layer 270 is in direct contact with the reinforcement member 280.

As shown in FIG. 15, in the printed wiring board 212, the third conductive particle 271c includes the first low-melting-point metal layer 291 formed on its periphery; the substrate film 260 is in direct contact with the adhesive layer 270; and a third low-melting-point metal layer 293 is formed between the adhesive layer 270 and the reinforcement member 280.

As shown in FIG. 16, in the printed wiring board of the present invention 213, the third conductive particle 271c includes the first low-melting-point metal layer 291 formed on its periphery; the second low-melting-point metal layer 292 is formed between the substrate film 260 and the adhesive layer 270; and the third low-melting-point metal layer 293 is formed between the adhesive layer 270 and the reinforcement member 280.

The second low-melting-point metal layer 292 may cover the entire surface of the substrate film 260 as shown in FIG. 14 and FIG. 16, or may cover only a portion of the ground circuit 262a.

The third low-melting-point metal layer 293 may cover the entire surface of the reinforcement member 280 as shown in FIG. 15 and FIG. 16, or may cover only a portion of the reinforcement member 280.

When the printed wiring board of the present invention includes the second low-melting-point metal layer 292, the second low-melting-point metal layer 292 has the following features.

The second low-melting-point metal layer 292 is not limited, but preferably contains at least one selected from the group consisting of indium, tin, lead, and bismuth.

These metals have melting points and conductivity suitable to form the second low-melting-point metal layer 292.

Preferably, the second low-melting-point metal layer 292 is formed from a metal having a melting point of 300° C. or lower.

When the second low-melting-point metal layer 292 is formed from a metal having a melting point of 300° C. or lower, the second low-melting-point metal layer 292 is easily softened, suitably improving the adhesion between the substrate film 260 and the adhesive layer 270.

In the production of the printed wiring board of the present invention, the second low-melting-point metal layer 292 is first heated and softened. The heating temperature will be high when the second low-melting-point metal layer 292 is formed from a metal having a melting point higher than 300° C., making the printed wiring board of the present invention susceptible to thermal damage.

Preferably, the second low-melting-point metal layer 292 has a thickness of 0.1 to 50 μm.

When the second low-melting-point metal layer 292 has a thickness less than 0.1 μm, the amount of the metal constituting the second low-melting-point metal layer 292 is small, so that the adhesion between the substrate film 260 and the adhesive layer 270 is less likely to improve.

The second low-melting-point metal layer 292 having a thickness more than 50 μm is thick, and is thus likely to significantly change its shape when heated. Thus, the shape of the printed wiring board is likely to be deformed.

Preferably, the second low-melting-point metal layer 292 contains a flux.

The presence of the flux in the second low-melting-point metal layer 292 facilitates improving the adhesion between the substrate film 260 and the adhesive layer 270 when the metal constituting the second low-melting-point metal layer 292 is softened.

Any known flux can be used. Examples include polyvalent carboxylic acids, lactic acid, citric acid, oleic acid, stearic acid, glutamic acid, benzoic acid, glycerol, and rosin.

When the printed wiring board of the present invention includes the third low-melting-point metal layer 293, preferably, the third low-melting-point metal layer 293 has the following features.

The third low-melting-point metal layer 293 is not limited, but preferably contains at least one selected from the group consisting of indium, tin, lead, and bismuth.

These metals have melting points and conductivity suitable to form the third low-melting-point metal layer 292.

Preferably, the third low-melting-point metal layer 293 is formed from a metal having a melting point of 300° C. or lower.

When the third low-melting-point metal layer 293 is formed from a metal having a melting point of 300° C. or lower, the third low-melting-point metal layer 293 is easily softened, suitably improving the adhesion between the adhesive layer 270 and the reinforcement member 280.

In the production of the printed wiring board of the present invention, the third low-melting-point metal layer 293 is first heated and softened. The heating temperature will be high when the third low-melting-point metal layer 293 is formed from a metal having a melting point higher than 300° C., making the printed wiring board susceptible to thermal damage.

Preferably, the third low-melting-point metal layer 293 has a thickness of 0.1 to 50 μm.

When the third low-melting-point metal layer 293 has a thickness less than 0.1 μm, the amount of the metal constituting the third low-melting-point metal layer 293 is small, and the adhesion between the adhesive layer 270 and the reinforcement member 280 is less likely to improve.

The third low-melting-point metal layer 293 having a thickness more than 50 μm is thick, and is thus likely to significantly change its shape when heated. Thus, the shape of the printed wiring board is likely to be deformed.

Preferably, the third low-melting-point metal layer 293 contains a flux.

The presence of the flux in the third low-melting-point metal layer 293 facilitates improving the adhesion between the adhesive layer 270 and the reinforcement member 280 when the metal constituting the third low-melting-point metal layer 293 is softened.

Any known flux can be used. Examples include polyvalent carboxylic acids, lactic acid, citric acid, oleic acid, stearic acid, glutamic acid, benzoic acid, glycerol, and rosin.

The method of producing these printed wiring boards 210 to 113 may be the same as the method of producing the printed wiring board 10, except that the third conductive particles are prepared instead of the first conductive particles in the conductive particle preparing step (1) and the second low-melting-point metal layer is formed on the substrate film or the third low-melting-point metal layer is formed on the adhesive layer in the adhesive layer forming step (3) or the reinforcement member disposing step (4).

These low-melting-point metal layers may be formed by a method such as plating.

### REFERENCE SIGNS LIST

10, 11, 12, 13, 110, 111, 112, 210, 211, 212, 213 printed wiring board
60, 160, 260 substrate film
61, 161, 261 base film
62, 162, 262 printed circuit
62a, 162a, 262a ground circuit
63, 163, 263 insulating layer
63a hole
70, 170, 270 adhesive layer
71, 171, 271 conductive particle
71a first conductive particle
72, 172, 272 adhesive resin
80, 180, 280 reinforcement member
91, 291 first low-melting-point metal layer
92, 192, 292 second low-melting-point metal layer
93, 293, 293 third low-melting-point metal layer
171b second conductive particle
271c third conductive particle

1. A printed wiring board comprising:
a substrate film including a base film and a printed circuit including a ground circuit;
an adhesive layer formed on the substrate film; and
a conductive reinforcement member formed on the adhesive layer,
wherein the adhesive layer contains conductive particles and an adhesive resin,
a third low-melting-point metal layer is formed between the adhesive layer and the reinforcement member,
the ground circuit is electrically connected to the reinforcement member via the third low-melting-point metal layer.

2. The printed wiring board according to claim 1,
wherein the third low-melting-point metal layer is formed from a metal having a melting point of 300° C. or lower.

3. The printed wiring board according to claim 1,
wherein the third low-melting-point metal layer has a thickness of 0.1 to 50 μm.

4. The printed wiring board according to claim 1,
wherein the third low-melting-point metal layer contains a flux.

5. The printed wiring board according to claim 1,
wherein the conductive particles are at least one selected from the group consisting of first conductive particles each including a non-conductive core particle and a first low-melting-point metal layer formed on the non-conductive core, intrinsically conductive second conductive particles, and third conductive particles each including a conductive core particle and a first low-melting-point metal layer formed on the conductive core.

6. The printed wiring board according to claim 5,
wherein the conductive particles are the first conductive particles and/or third conductive particles, and
the first low-melting-point metal layer is formed from a metal having a melting point of 300° C. or lower.

7. The printed wiring board according to claim 6,
wherein the first low-melting-point metal layer has a thickness of 0.1 to 50 μm.

8. The printed wiring board according to claim 6,
wherein the first low-melting-point metal layer contains a flux.

9. The printed wiring board according to claim 1,
wherein a second low-melting-point metal layer is formed between the substrate film and the adhesive layer.

10. The printed wiring board according to claim 9,
wherein the second low-melting-point metal layer is formed from a metal having a melting point of 300° C. or lower.

11. The printed wiring board according to claim 9,
wherein the second low-melting-point metal layer has a thickness of 0.1 to 50 μm.

12. The printed wiring board according to claim 9,
wherein the second low-melting-point metal layer contains a flux.

13. The printed wiring board according to claim 1,
wherein the conductive particles have an average particle size of 1 to 200 μm.
